(19) United States
(12) Patent Application Publication
(10) Pub. No.: US 2020/0403640 A1
(43) Pub. Date: Dec. 24, 2020

(54) METHOD FOR PERFORMING INTERLEAVING AND INTERLEAVER

(71) Applicant: LG ELECTRONICS INC., Seoul (KR)

(72) Inventors: Kijun JEON, Seoul (KR); Bonghoe KIM, Seoul (KR); Kwangseok NOH, Seoul (KR)

(73) Assignee: LG ELECTRONICS INC., Seoul (KR)

(21) Appl. No.: 16/961,647

(22) PCT Filed: Jan. 10, 2019
(86) PCT No.: PCT/KR2019/000396

§ 371 Date: Jul. 10, 2020

Related U.S. Application Data
(60) Provisional application No. 62/616,452, filed on Jan. 12, 2018.

(51) Int. Cl. H03M 13/27; H03M 13/29; H03M 13/11; H03M 13/00

(52) U.S. Cl. CPC H03M 13/271; H03M 13/6522; H03M 13/114; H03M 13/2942

(57) ABSTRACT

A method for performing interleaving by a communication device may comprise the steps of: writing an input bit sequence in the column direction of a memory matrix; and reading the written bit sequence in the row direction of the memory matrix, wherein the writing step comprises a step of writing, for each row comprising only systematic bits in the input bit sequence, the systematic bits by using a method in which the priorities of the systematic bits are determined on the basis of a predetermined shuffling pattern. The communication device is capable of communicating with at least one of another communication device, a communication device related to an autonomous driving vehicle, a base station or a network.

### TECHNICAL FIELD

The present disclosure relates to a wireless communication system, and more particularly, to a method of performing interleaving and interleaver therefor.

### BACKGROUND ART

The future fifth generation (5G) system has considered a wireless sensor network (WSN), massive machine type communication (MTC), etc. where a small packet is intermittently transmitted to achieve massive connections, low costs, and low power services.

In the case of a massive MTC service, connection density requirements are strictly limited, but data rates and end-to-end (E2E) latency requirements are unrestricted (for example, connection density: up to 200,000/km², E2E latency: seconds to hours, and downlink/uplink (DL/UL) data rate: typically 1 to 100 kbps).

Interleaving is a technique for distributing concentrated bit errors over time and frequency in a wireless channel environment where burst errors such as fading frequently occur.

### DISCLOSURE

### Technical Problem

An object of the present disclosure is to provide a method of performing interleaving.

Another object of the present disclosure is to provide a communication device including an interleaver.

The technical objects that can be achieved through the present disclosure are not limited to what has been particularly described hereinabove and other technical objects not described herein will be more clearly understood by persons skilled in the art from the following detailed description. It will be appreciated by persons skilled in the art that the objects that could be achieved with the present disclosure are not limited to what has been particularly described hereinabove and the above and other objects that the present disclosure could achieve will be more clearly understood from the following detailed description.

### Technical Solution

In an aspect of the present disclosure, provided herein is a method of performing interleaving by a communication device. The method may include writing an input bit sequence in the column direction of a memory matrix and reading the written bit sequence in the row direction of the memory matrix. The writing may include writing systematic bits for each row consisting of only the systematic bits in the input bit sequence by determining the priorities of the systematic bits based on a predetermined shuffling pattern.

The input bit sequence may have a predetermined redundancy version (RV) index. The predetermined RV index may be one of indices except index 0.

The predetermined shuffling pattern may include a pattern for randomly determining the priorities of the systematic bits for each row consisting of only the systematic bits.

The shuffling pattern may include a pattern for reversing previously determined priorities for each row consisting of only the systematic bits.

The writing may include writing the input bit sequence in the column direction of the memory matrix until a given maximum column index, moving to a column index of a next row, and continuing the writing.

In another aspect of the present disclosure, provided herein is a communication device. The communication device may include an interleaver configured to write an input bit sequence in the column direction of a memory matrix and read the written bit sequence in the row direction of the memory matrix. When writing the input bit sequence, the interleaver may be configured to write systematic bits for each row consisting of only the systematic bits in the input bit sequence by determining the priorities of the systematic bits based on a predetermined shuffling pattern.

The input bit sequence may have a predetermined RV index. The predetermined RV index may be one of indices except index 0.

The predetermined shuffling pattern may include a pattern for randomly determining the priorities of the systematic bits for each row consisting of only the systematic bits.

The shuffling pattern may include a pattern for reversing previously determined priorities for each row consisting of only the systematic bits.

The interleaver may be configured to write the input bit sequence in the column direction of the memory matrix until a given maximum column index, move to a column index of a next row, and continue the writing.

### Advantageous Effects

The interleaver proposed in the present disclosure may not only ensure self-decoding performance and incremental redundancy gain but may also maximize chase combining gain in a channel coding chain.

It will be appreciated by persons skilled in the art that the effects that could be achieved with the present disclosure are not limited to what has been particularly described hereinabove and other advantages of the present disclosure will be more clearly understood from the following detailed description. That is, effects which are not intended by the present disclosure may be derived by those skilled in the art from the embodiments of the present disclosure.

### DESCRIPTION OF DRAWINGS

The accompanying drawings, which are included to provide a further understanding of the disclosure, illustrate embodiments of the disclosure and together with the description serve to explain the principle of the disclosure.

FIG. 1 is a diagram illustrating a wireless communication system for implementing the present disclosure.

FIG. 2 is a diagram illustrating a circular buffer and bit interleavers for redundancy version 3 (RV3) depending on each interleaver.

FIG. 3 is a diagram for explaining the concept of a systematic bit priority shuffling (SBPS) interleaver.

FIG. 4 is a conceptual diagram for explaining pure/contaminated systematic codeword sequences in a memory and the classification of corresponding pure/contaminated systematic codeword cell groups.

FIG. 5 is a diagram illustrating the hardware structure of an SBPS interleaver.

FIG. 6 is a diagram illustrating the signal to noise ratio (SNR) required for BLER≤10⁻¹ at each interleaver in RV0 and RV3 from MCS indices of 13 to 27.

FIG. 7 is a diagram illustrating the SNR required for BLER≤10⁻¹ at each interleaver in RV3 from MCS indices of 13 to 24.

FIG. 8 is a diagram schematically illustrating a procedure in which an interleaver in a communication device according to the present disclosure performs interleaving.

### BEST MODE

Reference will now be made in detail to the preferred embodiments of the present disclosure, examples of which are illustrated in the accompanying drawings. In the following detailed description of the disclosure includes details to help the full understanding of the present disclosure. Yet, it is apparent to those skilled in the art that the present disclosure can be implemented without these details. For instance, although the following descriptions are made in detail on the assumption that a mobile communication system includes 3GPP LTE system, the following descriptions are applicable to other random mobile communication systems in a manner of excluding unique features of the 3GPP LTE.

Occasionally, to prevent the present disclosure from getting vaguer, structures and/or devices known to the public are skipped or can be represented as block diagrams centering on the core functions of the structures and/or devices. Wherever possible, the same reference numbers will be used throughout the drawings to refer to the same or like parts.

In this document, it is assumed that a terminal commonly refers to a mobile or fixed user device such as a user equipment (UE), a mobile station (MS), an advanced mobile station (AMS), etc. In addition, it is assumed that a base station (BS) commonly refers to a random network node communicating with a terminal such as a Node B, an eNode B, an access point (AP), a gNode B, etc.

In a mobile communication system, a UE may receive information from a BS in downlink and transmit information in uplink as well. The information transmitted or received by the UE may include various kinds of data and control information. Various physical channels may be used depending on the type and usage of the information transmitted or received by the UE.

The following descriptions are applicable to various wireless access systems including code division multiple access (CDMA), frequency division multiple access (FDMA), time division multiple access (TDMA), orthogonal frequency division multiple access (OFDMA), single carrier frequency division multiple access (SC-FDMA), etc. The CDMA may be implemented by such a radio technology as universal terrestrial radio access (UTRA), CDMA 2000, and the like. The TDMA may be implemented with such a radio technology as global system for mobile communications/general packet radio service/enhanced data rates for GSM evolution (GSM/GPRS/EDGE). The OFDMA may be implemented with such a radio technology as institute of electrical and electronics engineers (IEEE) 802.11 (Wi-Fi), IEEE 802.16 (WiMAX), IEEE 802.20, evolved UTRA (E-UTRA), etc. The UTRA is a part of a universal mobile telecommunication system (UMTS). 3rd generation partnership project (3GPP) long term evolution (LTE) is a part of an evolved UMTS (E-UMTS) using the E-UTRA. The 3GPP LTE employs the OFDMA in downlink and the SC-FDMA in uplink. LTE-advanced (LTE-A) is an evolved version of the 3GPP LTE.

The specific terminology used herein is provided for better understanding of the present disclosure. The specific terminology may be modified into another form within the scope of the technical idea of the present disclosure.

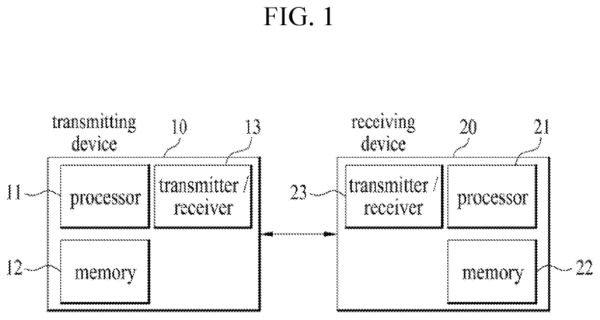

FIG. 1 is a diagram illustrating a wireless communication system for implementing the present disclosure.

Referring to FIG. 1, the wireless communication system may include a BS 10 and at least one UE 20. In downlink transmission, the BS 10 and the UE 20 may act as a transmitter and a receiver, respectively. The BS 10 may include a processor 11, a memory 12, and a radio frequency (RF) unit 13 (i.e., a transmitter and receiver). The processor 11 may be configured to perform the procedures and/or methods described in this document. The memory 12 may be connected to the processor 11 and configured to store various information for operating the processor 11. The RF unit 13 may be connected to the processor 11 and configured to transmit and/or receive a radio signal. The UE 20 may include a processor 21, a memory 22, and an RF unit 23 (i.e., a transmitter and receiver). The processor 21 may be configured to perform the procedures and/or methods described in this document. The memory 22 may be connected to the processor 21 and configured to store various information for operating the processor 21. The RF unit 23 may be connected to the processor 21 and configured to transmit and/or receive a radio signal. The BS 10 and/or UE 20 may have a single or multiple antennas. When at least one of the BS 10 and UE 20 has multiple antennas, the wireless communication system may be referred to as a multiple input multiple output (MIMO) system.

In the present specification, the processor 21 of the UE 20 and the processor 11 of the BS 10 are in charge of processing data and signals except transmission, reception, and storage functions. Thus, for clarity, the processors 11 and 21 are not mentioned separately. In other words, even though the processors 11 and 21 are not mentioned, a series of operations including data processing except transmission and reception may be assumed to be performed by the processor 11 and 21.

Radio protocol layers between the BS 10 and UE 20 in the wireless communication system (network) may be classified into Layer 1 (L1), Layer 2 (L2), and Layer 3 (L3) based on three lower layers of the open system interconnection (OSI) model well known in communication systems. A physical layer beloning to L1 provides an information transfer service via a physical channel. A radio resource control (RRC) layer beloning to L3 provides control resources between the UE and the network. The BS 10 and UE 20 may exchange RRC messages through RRC layers in the wireless communication network.

In the present specification, the processor 21 of the UE 20 and the processor 11 of the BS 10 are in charge of processing data and signals except transmission, reception, and storage functions of the UE 110 and BS 105, respectively. Thus, for clarity, the processors 155 and 180 are not mentioned separately. In other words, even though the processors 155 and 180 are not mentioned, a series of operations including data processing except the transmission, reception, storage functions may be assumed to be performed by the processor 155 and 180.

Interleaving is a technique for distributing concentrated bit errors over time and frequency in a wireless channel environment where burst errors such as fading frequently occur.

The present disclosure proposes a systematic bit priority shuffling based interleaver for improving systematic bit priority diversity by re-arranging systematic bit priorities. The proposed interleaver is a part of a transceiver capable of not only ensuring self-decoding performance and incremental redundancy gain but also maximizing chase combining gain in a channel coding chain. That is, the interleaver of the present disclosure may be one component of a communication device (e.g., a UE, a BS, etc.).

First, the problems of the conventional interleaver will be described.

Self-decoding performance, incremental redundancy (IR) gain, and chase combining gain are the most important properties in a coding chain, and an interleaver is a crucial block in terms of these properties. A row-column interleaver, a systematic bit priority (SBP) interleaver, and a reverse bit priority (RBP) interleaver are well-known interleavers. However, these interleavers may not provide three or more desired characteristics for the following reasons.

1) The row-column interleaver provides good self-decoding performance and IR gain in redundancy version 0 (RV0) compared to other RVs, but the lack of SBP diversity limits the chase combining gain in system bits. 2) The SBP interleaver provides good self-decoding performance for all RVs but has low IR gain and limited chase combining gain in systematic bits. 3) Although the RBP interleaver provides the chase combining gain when the same RV is retransmitted but has limited IR gain when other RVs are used.

In the following, capital and lowercase letters in boldface denote a matrix and a vector, respectively. In addition, [symbol] and [symbol] denote an i-th column (row) of matrix A and a submatrix of A from the i-th column (row) to a j-th column (row), respectively. Further, [symbol] denote a transpose operation, a modulo-N operation, a ceiling operation, and a flooring operation, respectively. Additionally, the following equation of (a)*=max(a, 0) is satisfied.

Table 1 summarizes symbols frequently used in the present disclosure. N, Nₚ, and K denote the length of a codeword transmitted with a mother code rate, the length of a punctured information sequence, and the length of an information sequence, respectively.

TABLE 1

| Notation | Description |
|---|---|
| N | Length of transmitted codeword of the mother code rate |
| Nₚ | Length of punctured information sequence |
| K | Length of information sequence |
| Eᵣ | Length of rate matching output sequence |
| N_{CB} | Circular buffer size |
| Qₘ | Modulation order |
| RVᵢ | Position value of ith Redundancy Version |
| B | Qₘ × (Eᵣ/Qₘ) interleaver matrix |

A code encoder maps a code block information vector i=[i¹, . . . , i^{k}]^{r} to a codeword vector with a size of d=[d₂, . . . d_{N}]^{r}. A corresponding codeword is recorded in a circular buffer with a size of N_{CB} (where N_{CB}≤N) (in the case of full buffer rate matching (FBRM), N_{CB}=N and in the case of limited buffer rate matching (LBRM), N_{CB}<N). The content of the circular buffer is read starting from a position of RVᵢ, and a circular buffer output sequence at RVᵢ may be given as shown in Equation 1.

$$\begin{matrix}c = {[ {c}_{1} , {c}_{2} , … , {c}_{{E}_{r}} ]}^{T} \\ = {[ {d}_{{RV}_{i} + 1} , {d}_{{RV}_{i} + 2} , … , {d}_{( {( {RV}_{i} + {E}_{r} - 1 )}_{{N}_{CB}} ) + 1} ]}^{T}\end{matrix} \qquad [ Equation 1 ]$$

A rate matching output sequence is mapped to Eᵣ/Qₘ modulation symbols, where M= [symbol] denotes the size of a modulator constellation.

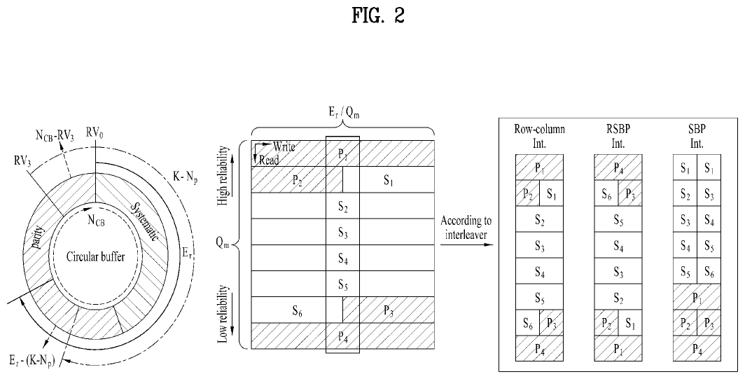

FIG. 2 is a diagram illustrating a circular buffer and bit interleavers for RV3 depending on each interleaver.

In the case of a row-column interleaver, mapping to modulation symbols may be performed as follows.

A code block c is interleaved by writing coded bits row-wise to a matrix B with a size of Qₘ×(Eᵣ/Qₘ), starting from the upper left corner and proceeding from the left to the right first and then from the top to the bottom. This may be represented as shown in Equation 2.

$$\begin{matrix}B = [ {b}_{1}^{c} , … , {b}_{\frac{{E}_{r}}{{Q}_{m}}}^{c} ] \\ = [ \begin{matrix}{c}_{1} & … & {c}_{{E}_{r} \text{/} {Q}_{m}} \\ ⋮ & ⋱ & ⋮ \\ {c}_{( {Q}_{m} - 1 ) ( \frac{{E}_{r}}{{Q}_{m}} ) + 1} & … & {c}_{{E}_{r}}\end{matrix} ]\end{matrix} \qquad [ Equation 2 ]$$

In Equation 2, Eᵣ denotes the length of the rate matching output sequence. The content of the matrix B is read column-wise, starting from the first (leftmost) column. A q-th row [symbol] is read as Qₘ-tuple [symbol] and mapped to a complex-valued symbol, x=I+jQ according to the procedure described in 3GPP TS 38.211 V15.0.0, NR; Physical channels and modulation (Release 15). According to the modulation mapping in 3GPP TS 38.211 V15.0.0, NR; Physical channels and modulation (Release 15), the Qₘ-tuple (b_{(q,1)}^{c}, . . . , b_{(q,Qm)}^{c}) bits are arranged in non-increasing order of bit-level capacity (that is, b_{(q,1)}^{c}, b_{(q,2)}^{c} has the highest bit-level capacity, [symbol] has the second highest bit-level capacity, and [symbol] has the lowest bit-level capacity).

Thus, as shown in FIG. 2, the coded bits in the top row of the interleaver matrix are mapped to high-reliability modulation bits, and the coded bits in the bottom row of the interleaver matrix are mapped to low-reliability modulation bits. Thus, according to this method, SBP mapping is applied to RV0, and PBP mapping is applied to other RVs.

In the case of the RBP interleaver, the Qₘ-tuple (b_{(q,1)}^{c}, . . . , b_{(q,Qm)}^{c}) bits are arranged in non-decreasing order of bit-level capacity as shown in FIG. 2 by deciphering (or reading) the bits from the bottom to the top in the row direction, instead of deciphering (or reading) the bits from the top to the bottom in the column direction based on the matrix B. Further, in the case of the SBP interleaver, all systematic bits may be allocated to higher rows than parity bits as shown in FIG. 2, regardless of the RV index.

Systematic Bit Priority Shuffling Based Bit Interleaver

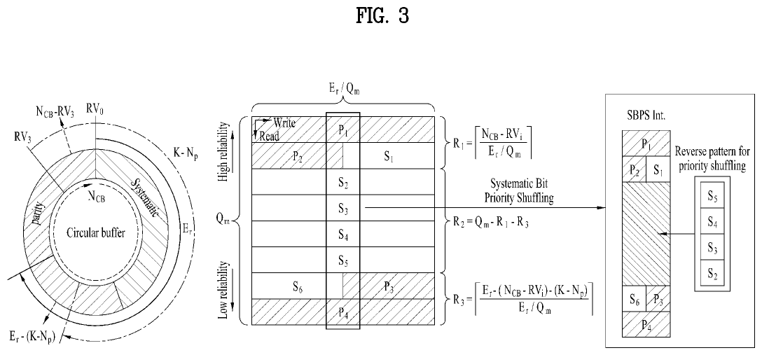

FIG. 3 is a diagram for explaining the concept of a systematic bit priority shuffling (SBPS) interleaver.

FIG. 3 illustrates the concept of a circular buffer and bit interleavers for RV3 of SBPS interleavers. To achieve great SBP diversity, the SBPS interleaver is applied to RV indices except RV0 (in the case of RV0, the row-column interleaver is adopted for the best self-decoding performance). A key feature of the proposed bit interleaver is that the chase combining gain is significantly improved due to SBP diversity and the priorities of systematic bits are shuffled except parity bits where the self-decoding performance and the IR gain are maintained at the row-column bit interleaver level. Shuffling may include randomly determining the priorities of the systematic bits for each row or applying a reverse pattern. The SBPS interleaver is read from the top to the bottom in the column direction as in the row-column interleaver.

However, the SBPS bit interleaver writes the systematic bits based on a shuffling pattern, unlike the row-column interleaver.

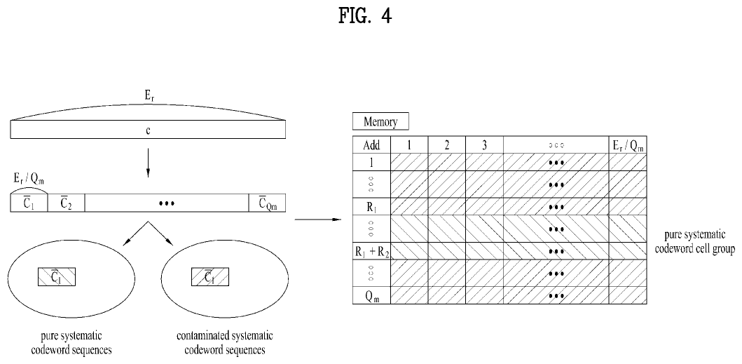

FIG. 4 is a conceptual diagram for explaining pure/contaminated systematic codeword sequences in a memory and classification of corresponding pure/contaminated systematic codeword cell groups.

In the case of a memory used for interleaving, a structure consisting of Qₘ×(Eᵣ/Qₘ) cells is considered as shown in the right part of FIG. 4 (Qₘ cells in the vertical direction and Eᵣ/Qₘ cells in the horizontal direction).

A codeword sequence with a length of Eᵣ may be divided into partial codeword sequences, each of which has a length of Eᵣ/Qₘ. In this case, there is a partial codeword sequence consisting of only information bit sequences, and such a partial codeword sequence is defined as a pure systematic codeword sequence. A vertical cell region of the memory where the pure systematic codeword sequence is stored is defined as a pure systematic codeword group. The pure systematic codeword sequences vary depending on a given RV index, and this may be expressed by Equation 3 below.

$$c \to \{ \begin{matrix}{\overline{c}}_{l} is the pure systematic codeword , & if l ∈ ℝ \\ {\overline{c}}_{l} is the contaminated systematic codeword , & elseif l ∈ {ℝ}^{o}\end{matrix} where \begin{matrix}{\overline{c}}_{l} = {c}_{[ ( l - 1 ) {E}_{r} \text{/} {Q}_{m} + 1 \text{:} {lE}_{r} \text{/} {Q}_{m} ]} \\ {R}_{1} = ⌈ \frac{{N}_{CB} - {RV}_{i}}{{E}_{r} \text{/} {Q}_{m}} ⌉ \\ {R}_{3} = {( ⌈ \frac{{E}_{r} - ( {N}_{CB} - {RV}_{i} ) - ( K - {N}_{p} )}{{E}_{r} \text{/} {Q}_{m}} ⌉ )}^{+} \\ {R}_{2} = {Q}_{m} - {R}_{1} - {R}_{3}\end{matrix} \qquad [ Equation 3 ]$$

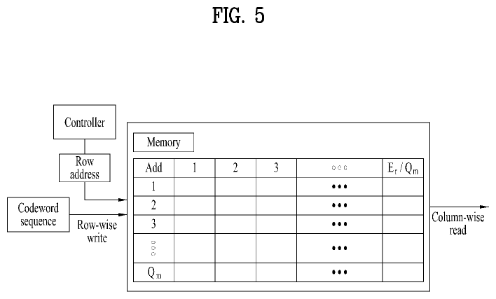

In Equation 3, [symbol] = [symbol] denotes a set of vertical cell indices in which the pure systematic codeword sequences are stored, and [symbol] ⁰ denotes a complement set except elements of a set [symbol] in a set [symbol] . This may be represented as shown in FIG. 5.

FIG. 5 is a diagram illustrating the hardware structure of an SBPS interleaver.

Hereinafter, the procedures of the SBPS interleaver will be described in detail.

1) Qₘ=row(s) of the matrix B may be divided into three groups as shown in Equation 4 below.

$$\begin{matrix}B = [ \begin{matrix}{B}^{( 1 )} \\ {B}^{( 2 )} \\ {B}^{( 3 )}\end{matrix} ] \\ = [ \begin{matrix}{B}_{[ 1 \text{:} {R}_{1} ]}^{r} \\ {B}_{[ {R}_{1} + 1 \text{:} {R}_{1} + {R}_{2} ]}^{r} \\ {B}_{[ {R}_{1} + {R}_{2} + 1 \text{:} {Q}_{m} ]}^{r}\end{matrix} ]\end{matrix} \qquad [ Equation 4 ]$$

In Equation 4, each of the first and third groups may be defined as a contaminated systematic codeword cell group, and the second group may be defined as a pure systematic codeword cell group. The pure systematic codeword cell group may be located in the memory as shown in FIG. 4.

2) Row-wise writing from the left to the right is performed from the top to the bottom in the contaminated systematic codeword cell group(s) (codeword sequences [symbol] and [symbol] are recorded (or written) in B⁽¹⁾ and B⁽³⁾, respectively).

3) A codeword sequence consisting of only systematic bits, [symbol] is recorded (or written) column-wise from the bottom to the top and row-wise from the left to the right as in the deterministic shuffling pattern of a pure systematic codeword cell group (B [symbol] ).

4) A codeword sequence written in B is deciphered (or read) column-wise from the top to the bottom, starting from the left to the right.

Extension of Systematic Bit Priority Shuffling Based Bit Interleaver

The proposed SBPS interleaver may be extended to various forms. First, row (s) consisting of systematic bits and parity bits are included in a group in which the row (s) are written according to a specific shuffling pattern. This shuffling method may also be applied to overlapping parity bits for each RV index.

Performance Evaluation of Systematic Bit Priority Shuffling Based Bit Interleaver

For performance evaluation, base graph 1 (BG1) low-density parity-check (LDPC) codes of 3GPP TS 38.212 V15.0.0, NR; Multiplexing and channel coding (Release 15) are used with the following assumptions. That is, it is assumed that the channel model is additive white Gaussian noise (AWGN), the resource allocation is given by N′_{RE}=156, n_{PRB}=273, and N_{layer}=4, and the decoding algorithm is a sum-product algorithm (D. J. Mackay, “Good error-correcting codes based on very sparse matrices,” IEEE Trans. Inf. Theory, vol. 45, no. 2, pp. 399-431, March 1999) based layered decoding (SPA-LD) algorithm with a maximum repetition number of 25. For a specific MCS index, N_{CB}, Eᵣ, and RVᵢ are determined by transport block size determination and codeblock segmentation under the condition of N′_{RE}, n_{PRB}, and N_{layer}. For example, when MCS index=13, N_{CB}=25344, RV₁=6528, RV₂=12672, and RV₃=21504 in the FBRM, and N_{CB}=12624, RV₁=3072, RV₂=6144, and RV₃=10368 in the LBRM. Eᵣ is 14808 in both the FBRM and LBRM.

In Table 5.1.3.1-2 of 3GPP TS 38.213 V15.0.0, NR; Physical layer procedures for data (Release 15), the row-column interleaver, (P)SBP interleaver, and proposed SBPS interleaver are evaluated for MCS indices of 13 to 27 for both the FBRM and LBRM. Here, the reverse order is used as a pattern for shuffling systematic bits. Also, specific RV orders [0, 3] or [3] are focused for discussion. After retransmission, log likelihood ratios (LLRs) obtained from the initial transmission and retransmission are combined and sent to an LDPC decoder.

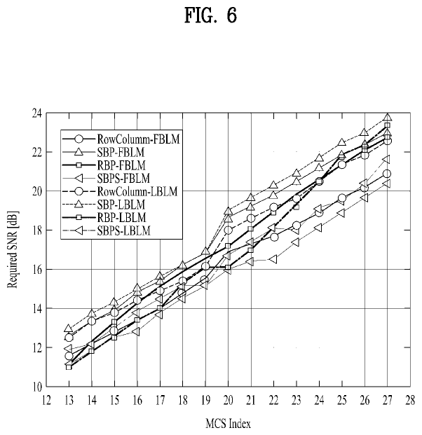

FIG. 6 is a diagram illustrating the signal to noise ratio (SNR) required for BLER≤10⁻¹ at each interleaver in RV0 and RV3 from MCS indices of 13 to 27.

FIG. 6 shows the SNR required for a target BLER of 10⁻¹ or less in RV0 and RV3 depending on the interleaver type. The SBPS interleaver outperforms the row-column interleaver for all MCS indices. In the LBRM, the performance difference increases since the SBP diversity increases due to a large number of overlapping systematic bits, compared to the FBRM. The SBPS interleaver has better performance than the SBP interleaver for all MCS indices in the both cases. In the case of the SBP interleaver versus the SBP interleaver, since the SBP diversity is maximized, the performance difference further increases compared to other interleavers. Compared to the RBP interleaver, the SBPS interleaver shows slightly poor performance for some low MCS indices but has good performance for other MCS indices. In particular, the RBPS interleaver provides lower IR gain than the SBPS interleaver even though it has higher SBP diversity than the SBPS interleaver, and thus the performance difference increases as the MCS index increases.

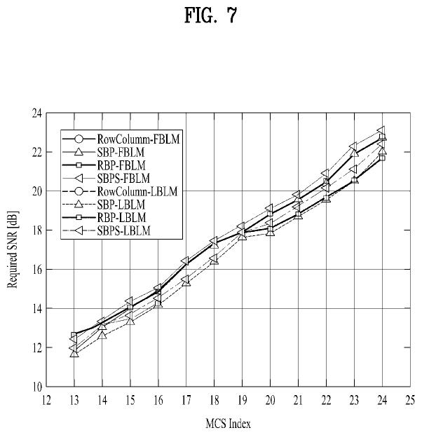

FIG. 7 is a diagram illustrating the SNR required for BLER≤10⁻¹ at each interleaver in RV3 from MCS indices of 13 to 24.

FIG. 7 shows the SNR required for a target BLER of 10⁻¹ or less in RV3 depending on interleaver types.

Compared to the row-column interleaver, the SBPS interleaver shows the same decoding performance since the SBPS interleaver does not change the priorities of systematic and parity bits. The SBPS interleaver shows slightly lower performance than the SBP interleaver since all SBP interleavers outperforms the SBPS interleaver. The SBPS interleaver shows lower performance than the RBP interleaver except for some low MCS indices since the priority of the systematic bits of the RBP interleaver is higher than that of the SBPS interleaver for almost all MCS indices.

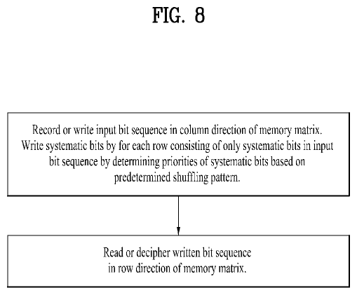

FIG. 8 is a diagram schematically illustrating a procedure in which an interleaver in a communication device according to the present disclosure performs interleaving.

Referring to FIG. 8, the interleaver writes (or records) an input bit sequence in the column direction of a memory matrix. In this case, the interleaver may write systematic bits for each row of the memory matrix consisting of only the systematic bits of the input bit sequence by determining the priorities of the systematic bits based on a predetermined shuffling pattern.

The predetermined shuffling pattern may include a pattern for determining the priorities of the systematic bits in a random manner for each row consisting of only the systematic bits. That is, as shown in FIG. 3, the interleaver may determine the priorities of the systematic bits randomly for each row consisting of only the systematic bits (rows S₂, S₃, S₄, and S₅ in the memory matrix). For example, when the interleaver assigns or determines the priorities in previous interleaving as follows: S₂, S₃, S₄, and S₅, the priorities may be assigned in the following order: S₄, S₃, S₅, and S₂ since the interleaver randomly assigns the priorities in current interleaving.

Alternatively, the shuffling pattern may include a pattern for reversing the previously determined priorities for each row consisting of only the systematic bits. Referring to FIG. 3, when the interleaver assigns or determines the priorities in previous interleaving as follows: S₂, S₃, S₄, and S₅, the priorities may be assigned in the following order: S₅, S₄, S₃, and S₂ since the priorities are reversed in current interleaving (see the right part of FIG. 3).

The interleaver writes the input bit sequence in the column direction of the memory matrix. Specifically, after writing the input bit sequence until a given maximum column index, the interleaver may move to a column index of the next row and continue the writing. The interleaver reads the written bit sequence in the row direction of the memory matrix.

The input bit sequence has a predetermined RV index, and in the 5G system, the predetermined RV index may be any one of indices 1 to 3.

In retransmission, the order of bits may be changed by defining a systematic bit pattern for each RV index. Such a systematic bit pattern may be provided by RRC signaling.

The aforementioned embodiments are achieved by combination of structural elements and features of the present disclosure in a predetermined manner. Each of the structural elements or features should be considered selectively unless specified separately. Each of the structural elements or features may be carried out without being combined with other structural elements or features. In addition, some structural elements and/or features may be combined with one another to constitute the embodiments of the present disclosure. The order of operations described in the embodiments of the present disclosure may be changed. Some structural elements or features of one embodiment may be included in another embodiment or may be replaced with corresponding structural elements or features of another embodiment. Moreover, it will be apparent that some claims referring to specific claims may be combined with other claims referring to the other claims other than the specific claims to constitute the embodiment or add new claims by means of amendment after the application is filed.

Those skilled in the art will appreciate that the present disclosure may be carried out in other specific ways than those set forth herein without departing from the spirit and essential characteristics of the present disclosure. The above embodiments are therefore to be construed in all aspects as illustrative and not restrictive. The scope of the disclosure should be determined by the appended claims and their legal equivalents, not by the above description, and all changes coming within the meaning and equivalency range of the appended claims are intended to be embraced therein.

### INDUSTRIAL APPLICABILITY

The method of performing interleaving and interleaver are industrially applicable to various wireless communication systems including the 5G communication system.

1. A method of performing interleaving by a communication device, the method comprising:
writing an input bit sequence in a column direction of a memory matrix; and
reading the written bit sequence in a row direction of the memory matrix,
wherein the writing comprises writing systematic bits for each row consisting of only the systematic bits in the input bit sequence by determining priorities of the systematic bits based on a predetermined shuffling pattern.

2. The method of claim 1, wherein the input bit sequence has a predetermined redundancy version (RV) index.

3. The method of claim 2, wherein the predetermined RV index is one of indices except index 0.

4. The method of claim 1, wherein the predetermined shuffling pattern comprises a pattern for randomly determining the priorities of the systematic bits for each row consisting of only the systematic bits.

5. The method of claim 1, wherein the shuffling pattern comprises a pattern for reversing previously determined priorities for each row consisting of only the systematic bits.

6. The method of claim 1, wherein the writing comprises writing the input bit sequence in the column direction of the memory matrix until a given maximum column index, moving to a column index of a next row, and continuing the writing.

7. A communication device comprising an interleaver configured to:
write an input bit sequence in a column direction of a memory matrix; and
read the written bit sequence in a row direction of the memory matrix,
wherein when writing the input bit sequence, the interleaver is configured to write systematic bits for each row consisting of only the systematic bits in the input bit sequence by determining priorities of the systematic bits based on a predetermined shuffling pattern.

8. The communication device of claim 7, wherein the input bit sequence has a predetermined redundancy version (RV) index.

9. The communication device of claim 8, wherein the predetermined RV index is one of indices except index 0.

10. The communication device of claim 7, wherein the predetermined shuffling pattern comprises a pattern for randomly determining the priorities of the systematic bits for each row consisting of only the systematic bits.

11. The communication device of claim 7, wherein the shuffling pattern comprises a pattern for reversing previously determined priorities for each row consisting of only the systematic bits.

12. The communication device of claim 7, wherein the interleaver is configured to write the input bit sequence in the column direction of the memory matrix until a given maximum column index, move to a column index of a next row, and continue the writing.

13. The communication device of claim 7, wherein the communication device is capable of communicating with at least one of another communication device, a communication device related to an autonomous driving vehicle, a base station or a network.
